(19) United States
(12) Patent Application Publication
(10) Pub. No.: US 2015/0301092 A1
(43) Pub. Date: Oct. 22, 2015

(54) VOLTAGE POLARITY DETECTION FOR DCM/CCM BOUNDARY DETECTION IN DC/DC CONVERTERS

(71) Applicant: ST-Ericsson SA, Plan-les-Ouates (CH)

(72) Inventor: Vratislav Michal, Grenoble (FR)

(21) Appl. No.: 14/438,735

(22) PCT Filed: Nov. 26, 2013
(86) PCT No.: PCT/EP2013/074764

§ 371 Date: Apr. 27, 2015

Related U.S. Application Data
(60) Provisional application No. 61/735,173, filed on Dec. 10, 2012.

(30) Foreign Application Priority Data
Nov. 27, 2012 (EP) 12306464.4

(51) Int. Cl. G01R 19/25

(52) U.S. Cl. CPC G01R 19/25

(57) ABSTRACT

There is described a circuit and a method of detecting a voltage polarity for the detection of a Continuous Conduction Mode to Discontinuous Conduction Mode boundary of a switched DC-DC converter. There is provided use of a dynamic current mirror to store in a first capacitor (C) a voltage representative of the conduction voltage (V_{DS(Φ1)}) of the power switch, at the end of a conduction cycle of said power switch. Also, an auto-zero comparator is used to charge the output voltage of the dynamic current mirror into a second capacitor (C₂), during the first phase of operation corresponding to a conduction cycle of the power switch, and to detect the polarity of the conduction voltage (V_{DS(t=TCLK})) of the power switch at the end of the first phase of operation of the DC-DC converter, by comparing the voltage stored in the second capacitor during the first phase of operation with the output voltage of the dynamic current mirror in a second phase of operation (Φ₂) corresponding to a non-conduction cycle of the power switch.

### BACKGROUND

1. Technical Field

The present disclosure generally relates to DC/DC convertors and methods for DC/DC conversion. More particularly, it concerns a voltage polarity detection circuit adapted for the detection of Continuous Conduction Mode (CCM) to Discontinuous Conduction Mode (DCM) boundary of a switched DC/DC converter.

It finds application, for instance, in power-management platforms for wireless devices such as mobile phones, smart phones, digital audio players, PDAs, e-books readers, or the like.

2. Related Art

The approaches described in this section could be pursued, but are not necessarily approaches that have been previously conceived or pursued. Therefore, unless otherwise indicated herein, the approaches described in this section are not prior art to the claims in this application and are not admitted to be prior art by inclusion in this section.

A DC/DC converter is an electronic circuit which converts a source of direct current (DC) from one voltage level to another, higher or lower voltage level. Electronic Switched Mode Power Supply (SMPS) circuits convert one DC voltage level to another, by controlling a switch to store the input energy temporarily and then release that energy to the output at a different voltage. The storage may be in either magnetic field storage components (inductors, transformers) or electric field storage components (capacitors). In magnetic DC/DC converters, the energy is periodically stored into and released from a magnetic field in an inductor or a transformer, typically in the range from 300 kHz to 10 MHz. By adjusting the duty cycle of the switching, i.e., the ratio of ON/OFF time of the switch, the amount of energy transferred to the output can be controlled. Usually, this is applied to control the output voltage, and therefore a switch driving circuit is adapted to sense the output voltage and generate a control signal for driving the switch.

With reference to FIGS. 1A-1C, SMPS circuits achieve synchronous DC/DC conversion by means a converter comprising an inductance L switched by at least one power switch S controlled by a pulse-width modulated control signal, a capacitor C, a flywheel diode D acting as a rectifier, and a switch driving circuit (not shown) adapted to generate the control signal. The power switch S may be a power Metal Oxyde Semiconductor (power-MOS) transistor of the N-conduction type (commonly referred to as a NMOS) or of the P-conduction type (commonly referred to as a PMOS).

Depending on the arrangement of the inductor L, switch S, capacitor C and rectifying diode D, the DC/DC converter can be of the Buck, Boost or Buck-Boost type. A DC/DC converter of the Buck type (as shown in FIG. 1A) allows reducing a DC input voltage Vᵢ or current to generate a lower DC output voltage or current. A DC/DC converter of the Boost type (as illustrated by FIG. 1B) allows elevating a DC input voltage Vᵢ or current to generate a higher DC output voltage or current. A DC/DC converter of the Buck-Boost type (as illustrated by FIG. 1C) is capable of performing both functions. In all types of DC/DC converters, the feedback circuit is adapted to generate the PWM control signal based on the DC output voltage Vₒ (or current) across the load R, so as to regulate said DC output voltage (or current) to a desired value.

The efficiency of such DC/DC converters has increased thanks to the use of synchronous rectification, by replacing the flywheel diode with a power-MOS with lower ON-resistance, thereby reducing losses and allowing generation of supply voltages of lower value.

As shown in FIG. 2, the switch S may be a PMOS power transistor M₃ arranged, in a power stage 10, in series with a NMOS power transistor M₂ acting as synchronous rectifier. Power transistors M₂ and M₃ are controlled by a driving signal CMD_N and a driving signal CMD_P, respectively. These signals may be generated by a Pulse-Width Modulation (PWM) unit 21 of the switch driving circuit 20, based on the output voltage Vₒ of the converter (not shown in FIG. 2 in which only the inductance L of the DC/DC converter is represented), that is to say the voltage across the load R as shown in FIGS. 1A-1C. In a Step-down (Buck) DC/DC converter, the output voltage is lower than the input voltage, and of the same polarity. In a Step-up (Boost) DC/DC converter, the output voltage Vₒ is higher than the input voltage Vᵢ. In a Single-Ended Primary-Inductor Converter (SEPIC) the output voltage Vₒ can be lower or higher than the input voltage Vᵢ (Buck-Boost).

Discontinuous Conduction Mode (DCM) is a mode of operation of the DC/DC converter wherein in order to protect inductance current I_{L} against polarity inversion during the conduction cycle of the power switch S, the power stage is disconnected (said power stage is in high impedance state). Likewise, Continuous conduction Mode (CCM) is a mode of the operation of DC/DC converter wherein the inductance current I_{L} is not inverted during the conduction cycle. The converter operates in DCM when low current is drawn by the load R, and in CCM at higher load current levels. Indeed, when the amount of energy required by the load R is small enough to be transferred in a time lower than the switching period, the current through the inductor falls to zero during part of this period.

The DCM/CCM boundary detection is a fundamental functionality of each modern DC/DC convertor, enabling the convertor to be operated in various operating modes, for instance pure PWM mode or pulse-skipping mode. Pulse skipping mode is an operation mode which enables to decrease the power consumption of the DC/DC converter and thus to increase the battery-life of the mobile device, e.g, mobile phone. The accurate detection of the boundary between DCM and CCM is an important issue having a major role on the power efficiency and reliability of the DC/DC converter.

The boundary between the DCM and CCM is defined by the zero-valley inductor current, i.e. zero-current at the end of the NMOS conduction cycle. If this zero-current is not properly detected, the conduction on the PMOS transistor body-diode occurs, which considerably increases the power losses of the converter. In fact, when inductor current is inverted, the output capacitor is discharged by the power stage. This is opposite compared to the required features of the power stage, which is supposed to drive the power into the output capacitor during the whole PWM conduction cycle.

Therefore, and as shown further in FIG. 2, the switch driving circuit 20 cooperates with a zero-current detection circuit 30, adapted to detect whether the inductor current I_{L} changes polarity during or at the end of the conduction period of the power switch, namely of the NMOS in the shown example. Said zero-current detection circuit 30 has an input 31 connected to the output of the power switch, i.e., the drain of the NMOS power transistor M₂ in the shown example, for receiving its V_{DS} voltage. Further, it has an output 32, whose output voltage V_{OUT} in indicative of the polarity of the V_{DS} voltage of the NMOS power transistor M₂ and is fed back to the switch driving circuit 20 along with the output voltage Vₒ of the DC/DC converter.

There are two methods which may be used in practice to detect the current polarity of the inductor current I_{L} at the end of NMOS conduction period. In a first method used in DC/DC convertors with low operating frequencies, the conduction on the body-diodes of the power-MOS is observed. In a second method suitable for DC/DC converters with higher switching frequency (when the non-overlapping time is not properly defined), the voltage V_{DS} on the power-MOS drain is observed.

The present disclosure addresses DC/DC converters relying on this second polarity detection method.

With reference to FIG. 3, there is observed the polarity of the V_{DS} voltage at the end of the conduction of the switch S, i.e., at time t=T_{CLK}, where V_{DS} voltage refers to the drain-source voltage of the output NMOS power transistor. In the case of a negative voltage as shown by the curve in dotted line, no inversion occurs during the conduction period of the NMOS, which means that the converter operates in the CCM mode of operation. In contrast, when the voltage V_{DS} at the end of the NMOS conduction period is positive as shown by the curve in continuous line, inversion occurs, and the pulse skipping mode is preferred in order to increase the power efficiency of the converter.

The voltage V_{DS(t=TCLK)} at the end of NMOS conduction period is equal to:

V_{DS}_{_{(t=TCKLK)}}=I_{L}_{_{(t=TCLK)}}·R_{DS}_{_{—}}_{N} (1)

where R_{DS}_{_{—}}_{N} is the ON-resistance of the power NMOS and is in order of 100 mΩ. It follows that polarity detection circuit must handle with very low voltage levels, with accuracy below 1 mV, and must therefore be extremely accurate.

Zero-current detection solutions known in the art are based on a comparator having a differential input pair. In order to ensure the required accuracy, this comparator must either be trimmed after fabrication (which is expensive) or must use a special design technique, leading to important silicon surface and current consumption. When the comparator is not trimmed, the system must exhibit a high robustness due to increased dispersion, which considerably lowers the power efficiency of the convertor. Sometimes, an additional sensing resistance is inserted to increase the V_{DS} voltage, which leads to additional power losses.

Other existing solutions also use sampling of the V_{DS} voltage at the end of NMOS conduction period, which is subsequently evaluated with a slower, but more accuracy, differential pair based comparator.

Reference US 2011/291632 discloses a power converter which includes a power converting unit and a switch driving circuit. A zero-current detector is configured to adjust the offset voltage based on a first detection voltage signal generated by a switch driving circuit and to generate a zero-current detecting signal based on the offset voltage. The offset voltage and the zero-current detecting signal are associated with a current in the power converting unit.

This solution requires a high performance, i.e., high speed and high accuracy comparator, however leading to high power consumption, or requires post-fabrication trimming of the comparator to enhance its quality. Obtaining such high quality comparator contributes to an important part of the DC-DC convertor design, and it costs lots of resources.

An accurate CCM to DCM boundary detection would allow to improve the converter device features such as efficiency, and reliability of the control. This is a challenging improvement in particular for the devices having very low resistance of power switches. The design of a new offset-free polarity detection circuit can allow further improvement of the DC-DC convertors efficiency, mainly for higher switching frequencies, as required by the new power-management platforms for e.g. wireless devices.

### SUMMARY

To address these needs, embodiments of the proposed solution rely on detecting the inversion of the coil current at the end of the NMOS conduction cycle, defining the crossing of the DCM/CCM boundary, by using a design based on dynamic current mirror and auto-zero comparator providing an offset-free and very fast polarity detection.

More particularly, a first aspect relates to a voltage polarity detection circuit adapted for the detection of a Continuous Conduction Mode to Discontinuous Conduction Mode boundary of a power switch in a switched DC/DC converter, said circuit comprising:
an input for receiving an input voltage representative of the conduction voltage of the power switch;
an output for outputting a voltage polarity detection signal;
a dynamic current mirror having an input connected to the input of the circuit through a first capacitor, and an output, said dynamic current mirror being controlled to store a voltage representative of the input voltage in the first capacitor at the end of a conduction cycle of the power switch; and,
an auto-zero comparator having a first input connected to the output of the dynamic current mirror, a second input connected to a second capacitor, and an output connected to the output of the circuit, said auto-zero comparator being controlled to:
   charge the output voltage of the dynamic current mirror into the second capacitor, during a first phase of operation corresponding to the conduction cycle of the NMOS power switch; and,
   detect the polarity of the input voltage at the end of the first phase of operation, by comparing the voltage stored in the second capacitor with the output voltage of the dynamic current mirror in a second phase of operation corresponding to a non-conduction cycle of the power NMOS switch.

The dynamic current mirror acts as an input memory element and a first comparator stage, whereas the auto-zero comparator acts as a fast output stage providing additional voltage gain of the voltage polarity detection circuit. As it will become apparent from reading the following description of embodiments, the proposed circuit has the further advantages of having no inherent comparison offset and of having a very high detection speed (in the order of a few nanoseconds), along with very low power consumption.

A second aspect relates to a method of detecting a voltage polarity for the detection of a Continuous Conduction Mode to Discontinuous Conduction Mode boundary of a power switch used in a switched DC-DC converter, comprising:
using a dynamic current mirror to store in a first capacitor a voltage representative of the conduction voltage of the power switch, at the end of a conduction cycle of the power switch; and,
using an auto-zero comparator to:
   charge the output voltage of the dynamic current mirror, into a second capacitor during a first phase of operation corresponding to the conduction cycle of the power switch; and,
   detect, the polarity of the conduction voltage of the power switch at the end of the first phase of operation, by comparing the voltage stored in the second capacitor during the first phase of operation with the output voltage of the dynamic current mirror in a second phase of operation corresponding to a non-conduction cycle of the power switch.

A third aspect relates to a DC-DC converter comprising a voltage polarity detection circuit according to the first aspect.

A fourth aspect relates to a wireless device comprising a Power Management Unit (PMU) having a DC-DC converter circuit according to the third aspect.

### BRIEF DESCRIPTION OF THE DRAWINGS

Embodiments of the present invention are illustrated by way of example, and not by way of limitation, in the figures of the accompanying drawings, in which like reference numerals refer to similar elements and in which:

FIGS. 1A, 1B and 1C are schematic views of a buck DC-DC converter, a boost DC-DC converter, and a buckboost DC-DC converter, respectively.

FIG. 2 is a schematic view of a synchronous rectification DC-DC converter having a pull-up PMOS transistor and a pull-down NMOS transistor.

FIG. 3 is a graph of the drain voltage of the NMOS transistor as a function of time over the switching cycle of the DC-DC converter of FIG. 2.

FIG. 4 is a schematic block diagram of a voltage polarity detection circuit used for the DCM/CCM boundary detection according to embodiments.

FIG. 5 are chronograms showing the waveform of the simplified schematic diagram from FIG. 4.

FIG. 6 is a detailed schematic block diagram of a voltage polarity detection circuit used for the DCM/CCM boundary detection according to other embodiments.

FIG. 7 is a schematic block diagram of a wireless device incorporating a DC/DC converter as shown in FIG. 4 or 6.

### DESCRIPTION OF PREFERRED EMBODIMENTS

Various example embodiments will now be described more fully with reference to the accompanying drawings in which some embodiments are shown. The proposed inventive concepts may, however, be embodied in different forms and should not be construed as limited to the embodiments set forth herein. Rather, example embodiments are provided so that this disclosure is thorough and complete and fully conveys these inventive concepts to those skilled in the art.

Referring to FIG. 4, there is shown therein a schematic block diagram of a voltage polarity detection circuit suitable for the DCM/CCM boundary detection according to embodiments of the proposed solution.

Embodiments rely on the association of a dynamic current mirror (also known as “current copier”) together with a simple, i.e., low performance and low cost auto-zero comparator. In a dynamic current mirror, one and the same transistor is sequentially used at the input and the output of the mirror. Such current mirror is independent of the intrinsic and unavoidable mismatch between the at least two transistors of standard current mirrors or differential input pair, and thus has a very high accuracy. More details about dynamic current mirrors can be consulted in the book “Analogue IC Design: The Current-Mode Approach”—Chris Toumazou, F. J. Lidgey, David Haigh—1993—pp 302-303, Chapter 7.4 entitled “Principle of dynamic current mirrors”.

In the contemplated implementation, the dynamic current mirror acts as the input memory element and a first comparator stage, whereas the auto-zero comparator acts as a fast output stage providing additional voltage gain of the voltage polarity detection circuit. As it will become apparent from reading the following description of embodiments, the proposed circuit has the further advantages of having no inherent comparison offset and of having a very high detection speed (in the order of a few nanoseconds), along with very low power consumption.

As shown in FIG. 4, the voltage polarity detection circuit 10, also referred to as a zero-current detector in the present description, has an input 31 and an output 32. Only the NMOS power transistor M₂ of the power stage 10 is represented in FIG. 4. Also, the switch driving circuit 20 as shown in FIG. 2 is not represented in FIG. 4, in order to keep the latter as simple and readable as possible. However, the one with ordinary skills in the art will understand that the proposed zero-current detector of FIG. 4 is adapted to be substituted to the zero-current detector of FIG. 2, namely may have its input 31 terminal and output terminal 32 connected to the same elements of the power stage 10 and the switch driving circuit 20 as described above with reference to FIG. 2. More precisely, the input terminal 31 is connected to the output, i.e., the drain of the NMOS transistor M₂ of the power stage 10, and the output terminal 32 is connected to an input of the switch driving circuit 20 to feed-back the zero-current detection signal V_{OUT}.

In the embodiment shown if FIG. 4, the power stage 10 further comprises a delay unit 11, which is adapted to delay the control signal CMD_N by a given time t₀. This ensures the absence of overlapping between the conduction periods of the power switch M₂ controlled by signal CMD_N on one hand, and power transistor M₃ controlled by the control signal CMD_P on the other hand.

Embodiments of the proposed polarity detection circuit 30 used for the detection of the Direct Current Mode (DCM) of the power switch M₂ comprise a dynamic current mirror and an auto-zero comparator, the combination of which provides a fast, accurate and offset-free polarity detection.

As shown in FIG. 4, the dynamic current mirror may comprise a single NMOS transistor M₁, whose drain is connected to a current source 61 for receiving a constant current I₀ output from said current source. The source of M₁ is connected to the ground GND. The control gate of M₁ is connected to the input 31 of the circuit through a capacitor C₁ and a first switch SW₁. It is further connected to the ground GND through capacitor C₁ and a second switch SW₂. The control gate of M₁ is finally connected to its drain through a third switch SW₃. Let us call V_{HZ} the voltage at the node corresponding to the drain of transistor M1, which thus also corresponds to the output voltage of the dynamic current mirror.

Further, the auto-zero comparator may comprise a standard two stage Operational Amplifier (OA) whose non inverting input “+” is connected to the drain of M₁, whose inverting input “−” is connected to the ground through a capacitor C₂, and whose output is connected to its inverting input “−” through a fourth switch SW₄. Let us call V_{C2} the voltage across capacitor C₂, and V_{OUT} the voltage at the output of the AO. Voltage V_{OUT} is also the output voltage of the auto-zero comparator and, hence, the voltage at the output 32 of the polarity detection circuit 30.

In one example, switches SW₁, SW₂, SW₃ and SW₄ each comprise, for instance are implemented by, e.g., a NMOS transistor M₇, M₉, M₅ and M₁₂, respectively.

Switches SW₁, SW₃ and SW₄ on one hand, and switch SW₂, on the other hand, are driven by two complementary clock signals φ₁ and φ₂, respectively.

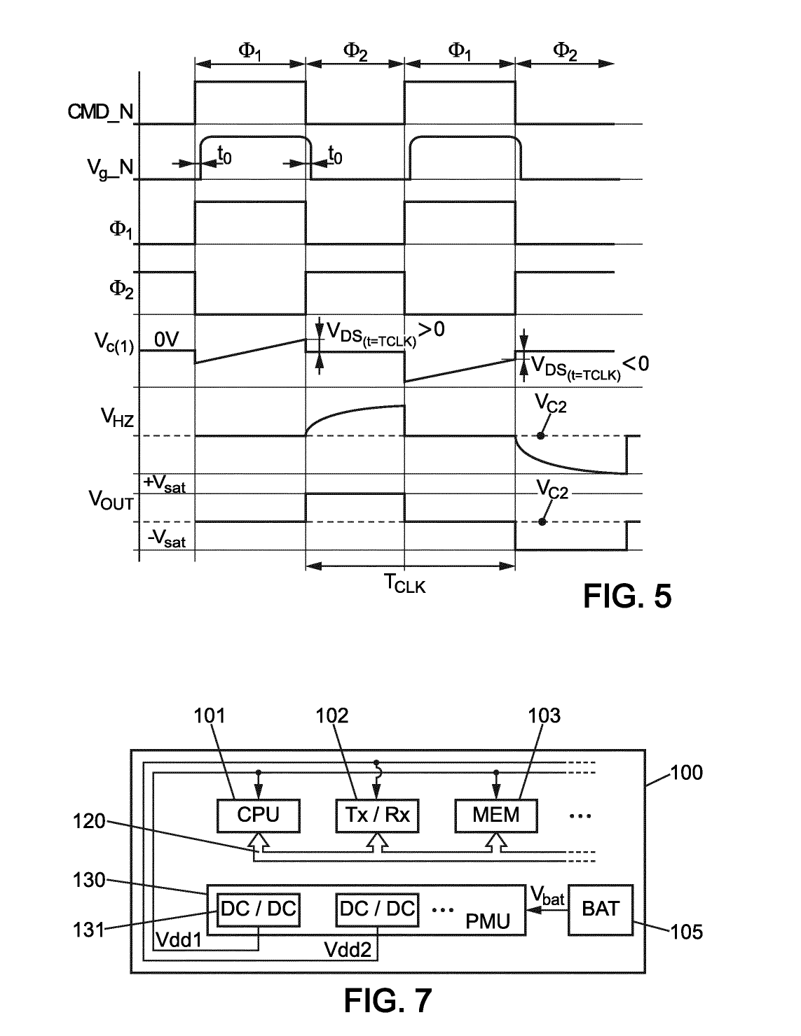

The operation of the circuit of FIG. 4 will now be detailed with reference to the simplified chronograms of FIG. 5.

The first chronogram at top of FIG. 5 shows the pulse-width modulated control signal CMD_N generated by the switch driving circuit 20 for driving the power switch M₂. The second chronogram corresponds to the voltage V_{g}_{_{—}}N on the control gate of transistor M₂, showing in particular the delay t₀ introduced by the delay unit 11 of the power stage 10. The third and fourth chronograms show the complementary clock signals Φ₁ and Φ₂. These clock signals Φ₁ and Φ₂ may be generated by the switch driving circuit 20. They have the same period as the control signals CMD_N and CMD_P, which may correspond to the period T_{CLK} of a master clock CLK of the power management unit which incorporates the DC-DC converter. Control signal CMD_N is in phase with clock signal Φ₁, and control signal CMD_P is in phase with clock signal Φ₂. Note, however, that a slight non-overlap of the φ₁ and φ₂ clock signals may be introduced.

The operation of the polarity detection circuit 30 is cyclic, one cycle corresponding to a period of the complementary clock signals Φ₁ and Φ₂. A cycle is divided in two phases of operation.

A first phase of operation is defined by the time when clock signal Φ₁ is active, for example at the high logical state, and control signal Φ₂ is inactive, at the low logical state in such example. Conversely, the second phase of operation is defined by the time when clock signal Φ₁ is inactive and control signal Φ₂ is active. In view of the above convention, the first phase of operation will sometimes be referred to as phase Φ₁, and the second phase of operation will be referred to as phase Φ₂, in what follows.

The NMOS transistor M₂ of the power stage is conductive during the first phase of operation (i.e., phase Φ₁), and is blocked during the second phase of operation (i.e., phase Φ₂). Stated otherwise, the first phase of operation of the polarity detection circuit corresponds to the conduction period of the power transistor M₂ of the DC-DC converter. Also, the switches SW₁, SW₃ and SW₄ are closed during the first phase of operation, and are open during the second phase of operation. Conversely, switch SW₂ is open during the first phase of operation, and is closed during the second phase of operation.

During phase Φ₁, the drain-source voltage V_{DS} of the power NMOS transistor M₂ is applied to the first terminal (1) of the memory capacitor C₁ through the closed switch SW₁. Switch SW₃, being closed, configures the transistor M₁ to be diode-connected. The terminal (2) of capacitor C₂ on the side of switch SW₃ is at the voltage gate-source voltage V_{GS(M1)} of transistor M₁, which is therefore given by:

$${V}_{GS ( M 1 )} = \sqrt{\frac{2 {I}_{D}}{{μ}_{0} {C}_{ox}} \frac{L}{W}} + {V}_{TH} \qquad ( 2 )$$

where:
I_{D} is the drain current flowing through M₁;
L and W designate the length and the width, respectively, of M₁; and,
V_{TH} is the threshold voltage of M₁.

If follows that, during phase Φ₁, the voltage V_{C1} across the capacitor C₁ is given by:

V_{C1}=V_{GS(M1)}−V_{DS(M2)} (3)

where V_{DS(M2)} is the drain-source voltage of the power transistor M₂.

It will be appreciated that voltage V_{C1} is thus directly representative of voltage V_{DS(M2)}(t), since the drain current I_{D} is flowing through M₁ is equal to the constant current I₀ from current source 61 (I_{D}=I₀), so that voltage V_{GS(M1)} is constant during phase Φ₁. Voltage V_{C1} across capacitor C₁ as a function of time is shown by the fifth chronogram from the top of FIG. 5.

During this phase φ₁, the auto-zero comparator, namely the Operational Amplifier OA, is configured as a voltage follower (switch SW₄ being closed). Thus, the substantially constant voltage V_{HZ} at the high-impedance node corresponding to the drain of transistor M₁, is recopied to the capacitor C₂ as voltage V_{C2}. Voltage V_{HZ} as a function of time is shown in the sixth chronogram from the top of FIG. 5. It may be noted, that an eventual offset of the comparator is added to the V_{C2}.

Let us now describe the configuration of the circuit in the second phase φ₂. In phase φ₂, terminal (1) of capacitor C₁ on the side of switch SW₂ is connected to the ground GND through closed switch SW₂, and switches SW₁, SW₃ and SW₄ are open. Whatever the polarity of the drain-source V_{DS} of M₁ voltage at the end of first phase Φ₁ (noted V_{DS(t=TCLK)} in FIG. 5), namely irrespective of whether voltage V_{DS(M2)} is positive or negative at the end of the conduction period of the NMOS transistor M₂, a complementary, i.e. negative or positive excursion will immediately appear on the gate of transistor M₁. Indeed, the voltage across capacitor C₁ remains constant upon switching of transistor M₂ from the conduction state to the non-conduction state. Further, from the end of phase φ₁ and beginning of phase φ₂ we have the following relationship:

V_{C1}=V_{GS(M1)} (4)

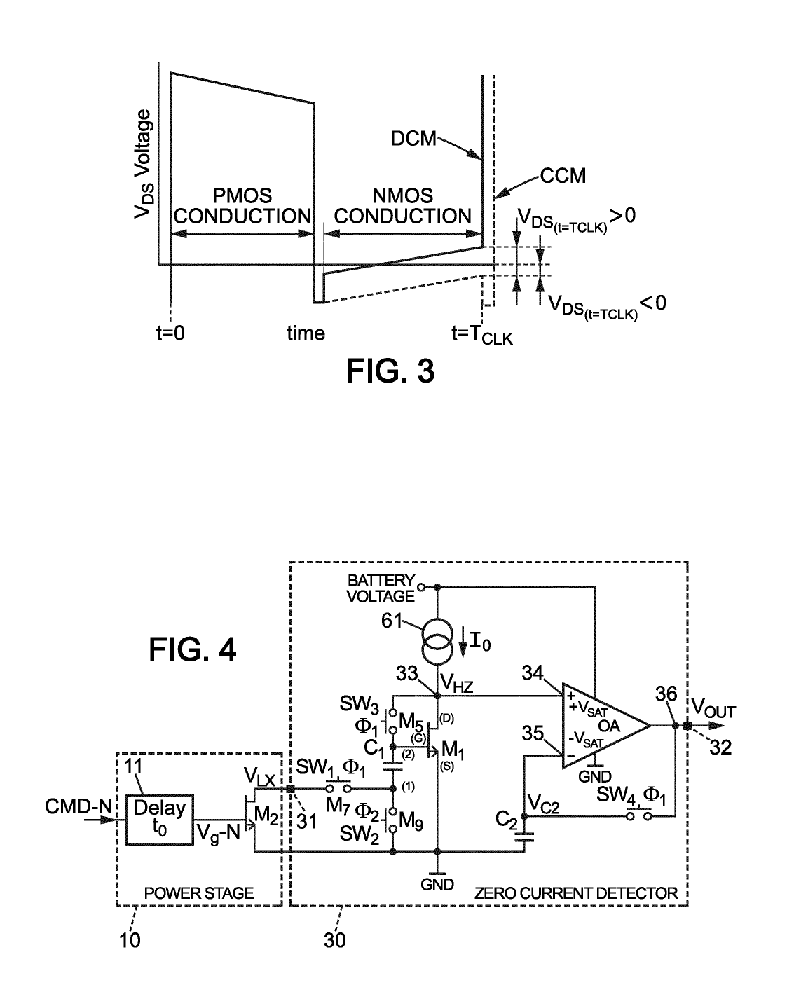

Thus, comparing above relations (3) and relation (4) at t=T_{CLK}, gives the following changes in the gate-source voltage V_{GS(M1)} of transistor M₁:
if the drain-source voltage V_{DS(t=TCLK)} of transistor M₂ at the end of phase φ₁ is positive (as shown on the left part of the fifth chronogram from top of FIG. 5 which corresponds to the case illustrated by the graph in continuous line of FIG. 3), then the gate-source voltage V_{GS} of transistor M₁ is shifted down by V_{DS(t=TCLK)}. It follows that voltage V_{GS(M1)} of transistor M₁ at the beginning of phase φ₂ is lower than at the end of phase φ₁ (which may be expressed as V_{GS(φ2)}<V_{GS(φ1)}); and, conversely,
if the drain-source voltage V_{DS(t=TCLK)} of transistor M₁ at the end of phase φ₁ is negative (as shown on the right part of the fifth chronogram from top of FIG. 5 which corresponds to the case illustrated by the graph in dotted line in FIG. 3), then the gate-source voltage V_{GS} of transistor M₁ is shifted up by the absolute value of V_{DS(t=TCLK)}. It follows that voltage V_{GS(M1)} of transistor M₁ at the beginning of phase φ₂ is higher than at the end of phase φ₁ (which may be expressed as V_{GS(φ2)}>V_{GS(φ1)}).

This implies the following changes in the drain-source voltage V_{DS} of transistor M₁, as shown in the sixth chronogram from the top of FIG. 5, on the left side, and on the right side, respectively, wherein the substantially constant value V_{C2} stored in capacitor C₂ is represented by a horizontal dotted line:
when V_{GS(φ2)}<V_{GS(φ1)}, then voltage V_{DS} of M₁ increases from voltage value V_{C2}; and, conversely,
in the opposite case when V_{GS(φ2)}>V_{GS(φ1)}, then the drain voltage V_{DS} of M₁ decreases from the value V_{C2} stored in capacitor C₂.

Let us now concentrate on the operation of the auto-zero comparator.

In phase φ₁, the switch SW₄ is closed thereby connecting the output voltage of the AO to its inverting, i.e., negative or “−” input. The AO is thus configured to operate as a voltage follower, as already stated above. Its output voltage, which thus corresponds to the V_{HZ} voltage plus any offset value of the AO, is charged into capacitor C₂.

In phase φ₂, the switch SW₄ is open and the AO thus operates as a comparator, whereby its output voltage is at +Vₛₐₜ if V_{HZ}>V_{C2}, and at −Vₛₐₜ if V_{HZ}<V_{C2}, where +Vₛₐₜ and −Vₛₐₜ are the positive and negative saturation voltages, respectively, of the AO, which corresponds to its high supply voltage and its low supply voltage, respectively. In one example, the high supply voltage corresponds to the battery voltage V_{I} of the device, and the low supply voltage corresponds to the potential of the ground GND, namely 0 Volt.

To summarize, and as is illustrated by the last chronogram at the bottom of FIG. 5, the output voltage V_{OUT} of the comparator is:
at voltage V_{C2} during phase φ₁, said voltage V_{C2} being substantially constant and mainly defined by the current I₀ output by current source 61;
at voltage +Vₛₐₜ=V_{I} (where V_{I} is, e.g., the battery voltage) during phase φ₂ in the case where V_{DS(t=TCLK)}>0, namely in the inverted coil current mode of operation of the DC/DC converter; and,
at voltage −Vₛₐₜ (e.g 0 Volt) during phase φ₂ in the case where V_{DS(t=TCLK)}<0, namely in the CCM mode of operation of the converter.

In other words, the output signal V_{OUT} at the output of the zero-current detector 30 is indicative of the polarity of the drain-source voltage V_{DS(t=TCLK)} of the power transistor M₂ at the end of its conduction phase φ₁. Yet in other words, this output signal V_{OUT} is representative of the result of the CCM/DCM boundary detection. Signal V_{OUT} is used by the switch driving circuit 20 as shown in FIG. 20, for defining the best switch strategy depending on the particular requirements of the contemplated application.

As can be understood by the one with ordinary skills in the art, using an auto-zero comparator as described above allows removing the effect of any offset of the AO, thus achieving an offset-free comparison result.

Besides, as the input voltage variation in gate-source voltage V_{GS} of transistor M₁ from phase φ₁ to phase φ₂ can be very low, the voltage excursion in the V_{HZ} node during phase φ₂ can be very slow. Nevertheless, one further advantage of the association of the dynamic current mirror with an auto-zero comparator is that voltage V_{HZ(Φ2)} is compared with voltage V_{HZ(Φ1)} (stored in C₂) by the auto-zero comparator whose output response is very fast. Therefore, as illustrated by the fifth, sixth and seventh chronograms from the top of FIG. 5 showing voltages V_{C1}, V_{HZ}, and V_{OUT}, respectively, even a slow voltage ramp can be detected substantially immediately after the end of phase φ₁ and beginning of phase φ₂. This is due to the fact, that the comparator is pre-biased, i.e. the starting-point of its output voltage variation is from an intermediate voltage value V_{C2}. This effects allow obtaining the comparison result in a very short time compared to the standard solutions.

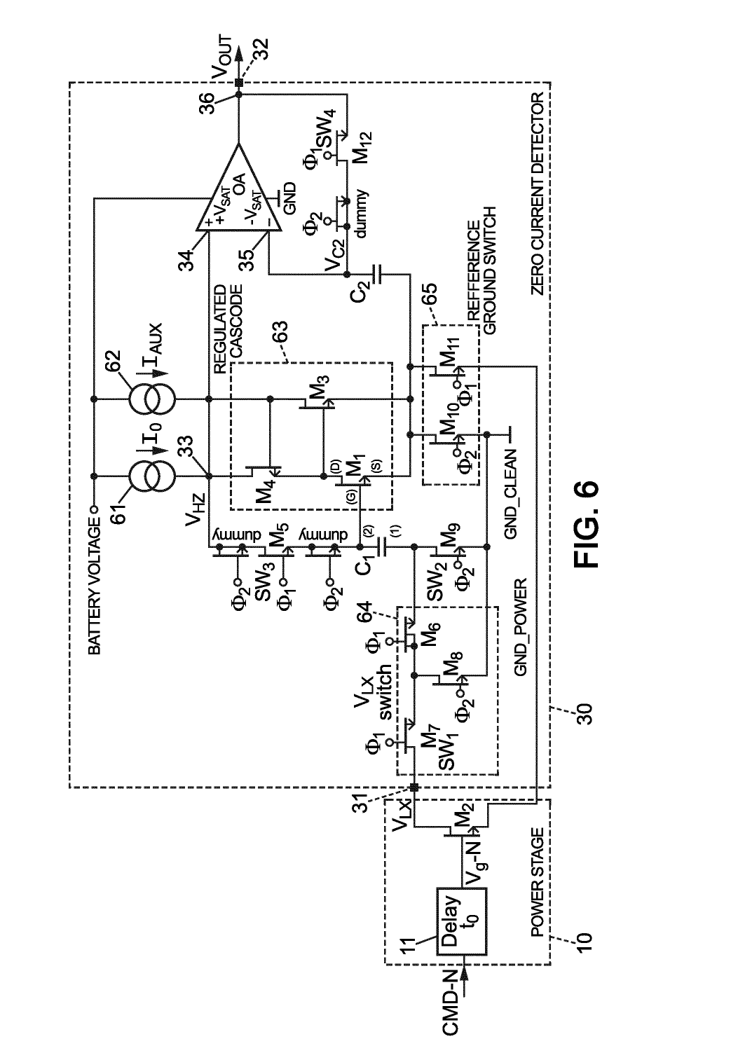

Further improvements of the proposed design will now be described with reference to the more elaborated schematic circuit diagram of FIG. 6.

One key aspect of the accuracy of proposed solution as described above is to protect the capacitor voltage V_{C1} during the switching from phase Φ₁ to phase Φ₂. This is because the capacitor C₁ stores the information about the compared voltage V_{DS} of the power NMOS transistor M₂ of the DC-DC converter, and it is critical not to alter this information V_{DS(t=TCLK)} at the end of the conduction phase φ₁ of the power transistor M₂.

It will be noted that small amount of error current is passing through capacitor C₁. This is due to the constant voltage at the plate (2) given by Eq. (2), and a small variation of the V_{DS(M2)} during the conduction of the NMOS transistor M₂. This variation is caused by the triangular shape of I_{L} (see shape of V_{C(1)} in the fifth graph from top of FIG. 5). As a result, in order to bring this current to a few nanoampers, the value of capacitor C₁ should be very small, for instance 1 pF, or even less. This, however, makes the V_{C1} voltage sensitive due to the possible charge injection caused by the switching. It will be appreciated that this is not valid for C₂ which can thus have a higher value.

Thus, some refinements of the basic design may be implemented, which will now be explained in more details. It will be appreciated, however, that these further embodiments may or not be implemented, either separately or in combination, in any manner suitable for the specific implementation. Stated otherwise, these further embodiments provide additional advantages but are not necessary for implementing the inventive principle of the proposed solution.

In one embodiment, for instance, provision can be made of a regulated cascode arrangement 63 for stabilising the V_{DS} voltage of transistor M₁. This solution allows preventing eventual detection errors which may be caused by the charge injection through the drain-to-gate parasitic capacitance of transistor M₁.

This result may be achieved by the stabilisation of V_{DS} voltage of M₁ with the help of at least one cascode stage in the dynamic current mirror, said cascode stage comprising two additional transistors M₃ and M₄. The source of M₃ is connected to the source of the main transistor M₁, its drain being connected to the battery voltage through an additional current source 62 delivering an additional constant current I_{AUX}, and it control gate being connected to the drain of the main transistor M₁. Transistor M₄ is cascaded with transistor M₁, i.e. arranged in series within the drain path of transistor M₁. More precisely, transistor M₄ is connected by its source to the drain of transistor M₁, and by its drain to the main current source 61 which delivers the main current I₀, having its control gate connected to the drain of transistor M₃ in the current path comprising the additional current source 62.

The stabilisation effect of this cascode arrangement is obtained at the cost of consumption of a small additional current I_{AUX} of e.g. a few micro-amperes (μA).

In other embodiments, dummy switches may be used to prevent the “clock feed-through” effect from the clock signals. By “dummy switches”, it must be understood dummy transistors, that is to say transistors of same technology as their associated main transistor, and having their current path short-circuited, namely their drain permanently connected to their source at silicon level. In the application considered here, the gate of any dummy transistor used as dummy switch receives a control clock signal which is complementary to the clock signal received by the gate of their associated main transistor.

For example, one or two such dummy switches may be associated to the third switch SW₃. For example, these dummy switches may be dummy transistors which have a size 0.5×W and 1×L, as compared with the size W and L of the main transistor M₅ of switch SW₃, respectively, and are provided in the current path of said main transistor M₅. In the shown example, one such dummy transistor is connected on each side of transistor M₅, namely on the drain side and the other on the source side of M₅. The former is adapted to prevent charge injection from transistor M₅ to the second capacitor C₂, and the latter is adapted to prevent charge injection from transistor M₅ to the first capacitor C₁. To that end, these dummy transistors are each controlled by the clock signal φ₂ which is complementary to the clock signal φ₁ controlling the transistor M₅ which implements the control switch SW₃.

It shall be appreciated that, other and possibly all control switches used in the zero-current may have one or two associated dummy switches. For instance, a dummy transistor may also be associated to the transistor M₁₂ of switch SW₄, as shown in FIG. 6 as well. More precisely, a dummy transistor is provided in the current path of the transistor M₁₂ implementing the control switch SW₄, on the side of the second capacitor C₂, said dummy transistor being controlled by the clock signal φ₂ which is complementary to the clock signal φ₁ controlling said main transistor implementing the fourth control switch. Being so arranged, the dummy transistor associated with transistor M₁₂ of switch SW₄ is adapted to prevent charge injection from said transistor M₁₂ to the second capacitor C₂.

In still other embodiments, provision can be made of a serially connected series and shunt switching arrangement 64, avoiding leakage of the inductor voltage V_{LX} at the drain of the power NMOS transistor M₂ when its body-diode is conducting.

In the shown example, such series and shunt switching arrangement is implemented at the first switch SW₁. Stated otherwise, the circuit comprises a series and shunt switching arrangement associated to the first switch SW₁. It may thus comprise, in addition to the serially connected transistor M₇ of switch SW₁ as described above, another serially connected transistor NMOS M₆ which is controlled by the same clock signal φ₁ as transistor M₇, and a parallel connected (i.e. shunt) NMOS transistor Mg controlled by a clock signal which is complementary to φ₁, for instance by the clock signal φ₂.

In yet other embodiments, the clock signals φ₁ and φ₂ are generated by the switch driving circuit so as to be slightly non-overlapping, in order to avoid the cross-conduction current through the switches SW₂ and SW₃. By “non-overlapping” it must be understood that both signals are not active, i.e. for instance at the logical high state, at the same time. As shown by the three first chronograms from the top of FIG. 5, clock signals φ₁ and φ₂ are driven by the NMOS control signal CMD_N instead of control voltage Vg_N. This allows sampling the drain-source voltage V_{DS(t=TCLK)} of the NMOS transistor M₁ at the end of phase φ₁ slightly before the end of the transistor conduction, when the power stage 10 is still in steady-state.

In further embodiments the voltage polarity detection circuit may further comprise a reference ground switching arrangement 65. This allows that that the reference ground is the power ground GND_POWER of the power stage of the DC/DC converter during the first phase of operation φ₁, and is a “clean” ground GND_CLEAN, distinct from said power ground, during the second phase of operation φ₂. Indeed, it is better that the reference ground of the voltage polarity detection circuit be the power ground of the power stage of the DC/DC converter during the first phase of operation φ₁ because this provides a better accuracy of the copy of the drain-source voltage V_{DS(M2)} of the power MOS transistor M₂ in the first transistor C₁. However, in the remaining of the time, that is to say during the second phase of operation φ₂, it is better that the reference ground the voltage polarity detection circuit be distinct from the power ground of the power stage of the DC/DC converter, because the latter may vary depending on the load current and may convey various kinds of interferences.

This result may be achieved, as shown in FIG. 4, by providing in the reference ground switching arrangement 65, a first NMOS transistor M₁₀ in series between the source of the main transistor M₁ of the dynamic current source and the clean ground GND_CLEAN terminal, which is controlled by signal φ₂, and a second NMOS transistor M₁₁ in series between the source of transistor M₁ and the power ground GND_POWER terminal of the power stage 10, said transistor M₁₁ being controlled by signal φ₁.

Finally, some embodiments may implement a dynamic bias in order to provide very low current consumption. According to such embodiments, the circuit is powered during the first phase of operation φ₁ of the DC/DC converter, only until the voltage V_{HZ} at the first input of the auto-zero comparator crosses the voltage V_{C2} at the second input of said auto-zero comparator, and is then turned off to save current consumption until the beginning of the next conduction cycle of the power switch M₂ of the DC/DC converter, that is to say until the beginning of the next iteration of the first phase of operation φ₁ of the DC/DC converter. In other words, the circuit is switched off and is placed e.g. in a sleep mode, until the beginning of the next NMOS conduction cycle.

The design presented above has a major impact on the efficiency and reliability of the DC/DC converter for e.g. mobile-phone platforms. Using such architecture can bring a significant advancement compared to existing solutions and can also find usage in similar products, such as any type of wireless devices.

The block diagram in FIG. 7 shows the elements of a wireless device 100 incorporating a DC/DC converter 110 as described above. Such a device 100 can be a mobile telephone, a smart phone, a digital audio player, a PDA, an e-book reader, or any other battery powered device.

The device 100 as shown comprises a control unit 101 such as a processor (CPU), and a number of functional units such as, for instance, a communication unit 102 for transmitting and receiving information to and from the outside, in particular by modulating a radio frequency carrier, a memory 103 which can store information in digital form, for example a piece of music, etc. The processor 101 communicates with the functional units like 102 and 103, via a communication bus 120. Each of the CPU and the functional units is powered from the battery voltage Vbat delivered by a battery 106, through a Power Management Unit (PMU) 130.

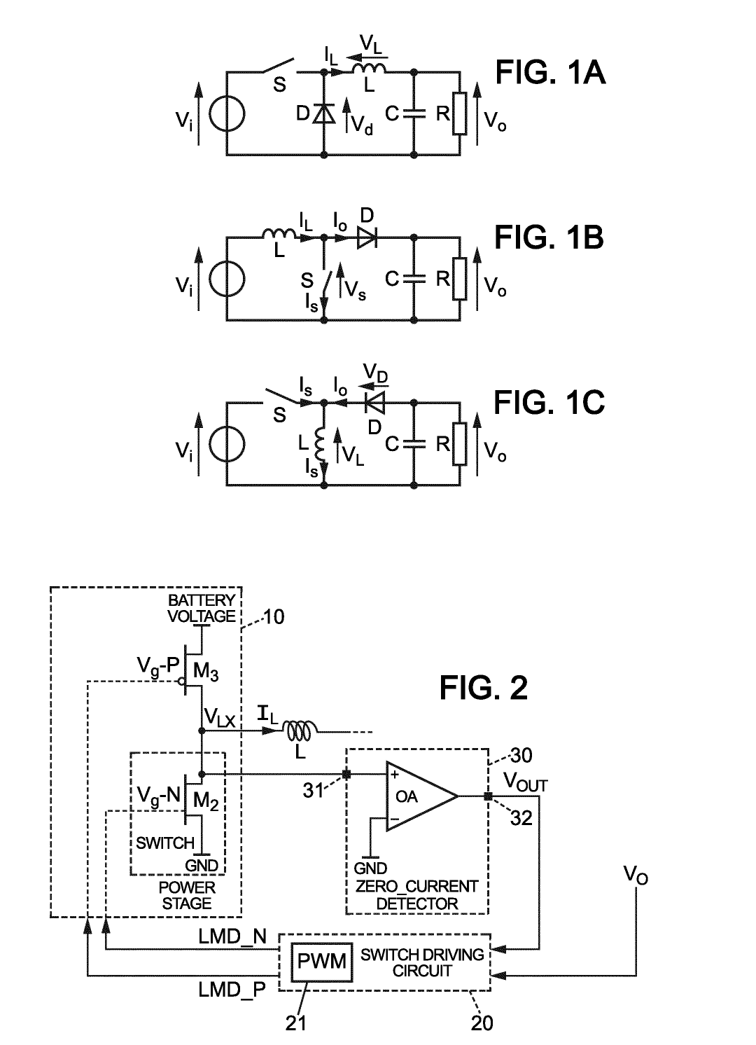

To generate supply voltages from the battery voltage Vbat, the PMU 130 comprises at least one voltage DC/DC converter 131 of the SMPS type, for which embodiments have been described above. More than one such DC/DC converter may be provided for generating a plurality of supply voltages Vdd1, Vdd2, . . . of different values for e.g. supplying respective groups of functional units, and/or respective functional blocks thereof. The DC/DC converters may be of any one of the buck, boost or buck-boost type, as previously described with reference to FIGS. 1A-1C.

Unless otherwise defined, all terms (including technical and scientific terms) used herein have the same meaning as commonly understood by one of ordinary skill in the art to which inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of inventive concepts.

The terminology used herein is for the purpose of describing particular embodiments only and is not intended to be limiting of inventive concepts. As used herein, the singular forms “a,” “an” and “the” are intended to include the plural aims as well, unless the context clearly indicates otherwise.

Also; expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

While there has been illustrated and described what are presently considered to be the preferred embodiments of the present invention, it will be understood by those skilled in the art that various other modifications may be made, and equivalents may be substituted, without departing from the true scope of the present invention. Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

The present invention can be implemented in hardware, software, or a combination of hardware and software. Any processor, controller, or other apparatus adapted for carrying out the functionality described herein is suitable. A typical combination of hardware and software could include a general purpose microprocessor (or controller) with a computer program that, when loaded and executed, carries out the functionality described herein.

The present invention can also be embedded in a computer program product, which comprises all the features enabling the implementation of the methods described herein, and which—when loaded in an information processing system—is able to carry out these methods. Computer program means or computer program in the present context mean any expression, in any language, code or notation, of a set of instructions intended to cause a system having an information processing capability to perform a particular function either directly or after either or both of the following a) conversion to another language. Such a computer program can be stored on a computer or machine readable medium allowing data, instructions, messages or message packets, and other machine readable information to be read from the medium. The computer or machine readable medium may include non-volatile memory, such as ROM, Flash memory, Disk drive memory, CD-ROM, and other permanent storage. Additionally, a computer or machine readable medium may include, for example, volatile storage such as RAM, buffers, cache memory, and network circuits. Furthermore, the computer or machine readable medium may comprise computer or machine readable information in a transitory state medium such as a network link and/or a network interface, including a wired network or a wireless network, that allow a device to read such computer or machine readable information.

A person skilled in the art will readily appreciate that various parameters disclosed in the description may be modified and that various embodiments disclosed and/or claimed may be combined without departing from the scope of the invention.

It is stipulated that the reference signs in the claims do not limit the scope of the claims, but are merely inserted to enhance the legibility of the claims.

1. A voltage polarity detection circuit adapted for the detection of a Continuous Conduction Mode to Discontinuous Conduction Mode boundary of a power switch in a switched DC/DC converter, said circuit comprising:
an input for receiving an input voltage representative of the conduction voltage of the power switch;
an output for outputting a voltage polarity detection signal;
a dynamic current mirror having an input connected to the input of the circuit through a first capacitor, and an output, said dynamic current mirror being controlled to store a voltage representative of the input voltage in the first capacitor at the end of a conduction cycle of the power switch; and,
an auto-zero comparator having a first input connected to the output of the dynamic current mirror, a second input connected to a second capacitor, and an output connected to the output of the circuit, said auto-zero comparator being controlled to:
charge the output voltage of the dynamic current mirror into the second capacitor, during a first phase of operation corresponding to the conduction cycle of the power switch; and,
detect the polarity of the input voltage at the end of the first phase of operation, by comparing the voltage stored in the second capacitor with the output voltage of the dynamic current mirror in a second phase of operation corresponding to a non-conduction cycle of the power switch.

2. The circuit of claim 1, wherein the dynamic current mirror comprises:
a main current source adapted to output a main constant current; and,
a single main MOS transistor whose drain is connected to the current source for receiving said constant current, whose source is connected to a first power supply, and whose control gate is connected:
to input of the dynamic current mirror through the first capacitor and a first control switch;
to the first power supply through the first capacitor and a second control switch; and,
to its drain through a third control switch.

3. The circuit of claim 1, wherein the auto-zero comparator comprises an Operational Amplifier whose non-inverting input is connected to the first input of the comparator, whose inverting input is connected to the first power supply through the second capacitor, and whose output is connected to the non-inverting input through a fourth control switch and to the output of the comparator.

4. The circuit of claim 1, wherein the first, third and fourth control switches on one hand, and the second control switch, on the other hand, are driven by a first and a second one, respectively, of two complementary clock signals, such that the first, third and fourth control switches are closed and the second control switch in open in the first phase of operation, and that the first, third and fourth control switches are open and the second control switch is closed in the second phase of operation.

5. The circuit of claim 1, wherein the dynamic current mirror further comprises a cascode stage having a first additional MOS transistor whose source is connected to the source of the main MOS transistor, whose drain is connected to an additional current source adapted to output an additional constant current, and whose control gate is connected to the drain of said main transistor, as well as a second additional MOS transistor whose source is connected to the drain of the main transistor, whose drain is connected to the main current source for receiving the main constant current, and whose control gate is connected to the drain of the first additional transistor.

6. The circuit of claim 4, wherein the third control switch is implemented by a main transistor, the circuit further comprising a first and/or a second dummy transistors provided in the current path of said main transistor implementing the third control switch, on either side of said main transistor implementing the third control switch, respectively, namely on the drain side and on the source side of said main transistor, respectively, said first and/or second dummy transistors each being controlled by a clock signal which is complementary to the clock signal controlling said main transistor implementing the third control switch.

7. The circuit of claim 6, wherein the first and/or second dummy transistors have a size 0.5×W and 1×L, as compared with the size W and L of said main transistor, respectively.

8. The circuit of claim 4, wherein the fourth control switch is implemented by a main transistor, the circuit further comprising a dummy transistor provided in the current path of said main transistor implementing the fourth control switch, on the side of the second capacitor, said dummy transistor being controlled by a clock signal which is complementary to the clock signal controlling said main transistor implementing the fourth control switch.

9. The circuit of claim 4, wherein the first control switch is implemented by a main transistor, the circuit further comprising a series and shunt switching arrangement associated to said main transistor implementing the first control switch, said series and shunt switching arrangement comprising, in addition to the serially connected main transistor implementing the first control switch, another serially connected transistor which is controlled by the same clock signal as said main transistor implementing the first control switch, and a parallel connected transistor controlled by a clock signal which is complementary to clock signal which controls said main transistor implementing the first control switch.

10. The circuit of claim 4, wherein the two complementary clock signals are non-overlapping.

11. The circuit of claim 2, further comprising a reference ground switching arrangement, so arranged that the first power supply is the power ground of the power stage of the DC/DC converter during the first phase of operation and is distinct from said power ground during the second phase of operation.

12. The circuit of claim 4, wherein the circuit is powered during the first phase of operation, only until the voltage at the first input of the auto-zero comparator crosses the voltage at the second input of said auto-zero comparator, and is then turned off until the beginning of the next conduction cycle of the power switch.

13. A method of detecting a voltage polarity for the detection of a Continuous Conduction Mode to Discontinuous Conduction Mode boundary of a power switch used in a switched DC-DC converter, comprising:
using a dynamic current mirror to store in a first capacitor a voltage representative of the conduction voltage of the power switch, at the end of a conduction cycle of said power switch; and,
using an auto-zero comparator to:
charge the output current of the dynamic current mirror into a second capacitor during a first phase of operation corresponding to the conduction cycle of the power switch; and,
detect the polarity of the conduction voltage of the power switch at the end of the first phase of operation, by comparing the voltage stored in the second capacitor during the first phase of operation with the output voltage of the dynamic current mirror in a second phase of operation corresponding to a non-conduction period of the power switch.

14. A DC/DC converter comprising:
a power stage having at least one power switch; and,
at least one voltage polarity detection circuit according to claim 1, for the detection of a Continuous Conduction Mode to Discontinuous Conduction Mode boundary of the power switch.

15. The DC/DC converter of claim 14, wherein the power switch comprises a power Metal Oxyde Semiconductor, MOS, transistor and wherein the input voltage of the voltage polarity detection circuit is the drain-source voltage of said power MOS transistor.

16. A mobile device comprising a DC/DC converter according to claim 15.
